(19) United States
(12) Patent Application Publication
(10) Pub. No.: US 2026/0269729 A1
(43) Pub. Date: Sep. 10, 2026

(54) MULTIPHASE VOLTAGE REGULATION CIRCUIT HAVING INTERLEAVED CLOCK CONTROL MECHANISM

(71) Applicant: ANPEC ELECTRONICS CORPORATION, HSINCHU (TW)

(72) Inventors: CHUN-KAI HSU, HSINCHU CITY (TW); CHIH-HENG SU, Hsinchu City (TW)

(21) Appl. No.: 19/209,753

(22) Filed: May 15, 2025

(30) Foreign Application Priority Data
Mar. 5, 2025 (TW) 114108009

(51) Int. Cl. H02M 3/158; H02M 1/00; H03K 23/40; H03L 7/085

(52) U.S. Cl. CPC H02M 3/1586; H02M 1/0025; H03L 7/085; H03K 23/40

(57) ABSTRACT

A multiphase voltage regulation circuit having an interleaved clock control mechanism includes a plurality of voltage regulators and a clock signal generator circuit. The clock signal generator circuit multiplies a target frequency by the number of the voltage regulators to obtain a reference frequency, and accordingly generates a reference clock signal in which each of a plurality of pulse waves has the reference frequency. The clock signal generator circuit divides the reference clock signal into a plurality of regulation clock signals, and outputs the regulation clock signals respectively to the voltage regulators. A frequency of each of pulse waves of the regulation clock signals is equal to the target frequency. Phases of each one of the regulation clock signals are respectively not overlapped with the phases of another of the regulation clock signals. The voltage regulators operate based on the plurality of regulation clock signals, respectively.

### CROSS-REFERENCE TO RELATED PATENT APPLICATION

This application claims the benefit of priority to Taiwan Patent Application No. 114108009, filed on Mar. 5, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a multiphase voltage regulation circuit, and more particularly to a multiphase voltage regulation circuit having an interleaved clock control mechanism.

### BACKGROUND OF THE DISCLOSURE

Voltage regulators are power supply devices and widely applied to various electronic circuits. The voltage regulator is configured to obtain an input voltage from an input power source, and modulate the input voltage to output an output voltage to a load for operation of the load. In order to supply power to a plurality of loads at the same time, a conventional multiphase voltage regulation circuit includes a plurality of voltage regulators. These plurality of voltage regulators are configured to respectively modulate the input voltage into the plurality of output voltages, and respectively supply the plurality of output voltages to the plurality of loads at the same time.

However, the plurality of voltage regulators of the conventional multiphase voltage regulation circuit obtain the input voltage at the same time, based a clock signal having a constant frequency. As a result, large ripples are generated in the input voltage and an input current of the input power source at the same time point, which causes an abnormality in the input power source.

In order to prevent the abnormality from occurring in the input power source, the conventional multiphase voltage regulation circuit further includes a plurality of input capacitors each having a large capacitance. These plurality of input capacitors are configured to provide a transient input current for reducing the ripple waves of the input power source, thereby protecting the input power source. However, those input capacitors are large in size and occupy large space, resulting in an increase in an overall size of the conventional multiphase voltage regulation circuit and an increase in cost.

### SUMMARY OF THE DISCLOSURE

In response to the above-referenced technical inadequacies, the present disclosure provides a multiphase voltage regulation circuit having an interleaved clock control mechanism. The multiphase voltage regulation circuit includes a plurality of voltage regulators and a clock signal generator circuit. The clock signal generator circuit is connected to the plurality of voltage regulators. The clock signal generator circuit is configured to use a frequency of a pulse wave of a target clock signal as a target frequency. The clock signal generator circuit is configured to multiply the target frequency by a number of the plurality of voltage regulators to obtain a reference frequency. The clock signal generator circuit is configured to generate a reference clock signal based on the reference frequency. A frequency of each of a plurality of pulse waves of the reference clock signal is equal to the reference frequency. The clock signal generator circuit is configured to divide the reference clock signal into a plurality of regulation clock signals, and output the plurality of regulation clock signals respectively to the plurality of voltage regulators. A frequency of each of a plurality of pulse waves of the plurality of regulation clock signals is equal to the target frequency. A plurality of phases of the plurality of pulse waves of each one of the plurality of regulation clock signals are respectively not overlapped with that of another of the plurality of regulation clock signals. Each of the plurality of voltage regulators is configured to obtain an input voltage from an input power source based on the regulation clock signal, and configured to modulate the input voltage into an output voltage.

As described above, the present disclosure provides the multiphase voltage regulation circuit having the interleaved clock control mechanism. The plurality of voltage regulators included in the multiphase voltage regulation circuit of the present disclosure obtain the input voltage from the input power source respectively at different time points, thereby effectively preventing large ripple waves from generating in the input voltage and an input current of the input power source. Therefore, the multiphase voltage regulation circuit of the present disclosure is capable of preventing an abnormality from occurring in the input power source under the condition that size of the multiphase voltage regulation circuit of the present disclosure is not increased.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a circuit diagram of a multiphase voltage regulation circuit having an interleaved clock control mechanism according to a first embodiment of the present disclosure;

FIG. 2 is a circuit diagram of a clock signal generator circuit included in a multiphase voltage regulation circuit having an interleaved clock control mechanism according to a second embodiment of the present disclosure;

FIG. 3 is a waveform diagram of signals of the multiphase voltage regulation circuit having the interleaved clock control mechanism according to a third embodiment of the present disclosure;

FIG. 4 is a waveform diagram of signals of the multiphase voltage regulation circuit having the interleaved clock control mechanism according to a fourth embodiment of the present disclosure;

FIG. 5 is a circuit diagram of a single voltage regulator and a clock signal generator circuit that are included in a multiphase voltage regulation circuit having an interleaved clock control mechanism according to a fifth embodiment of the present disclosure;

FIG. 6 is a circuit diagram of a single voltage regulator and a clock signal generator circuit that are included in a multiphase voltage regulation circuit having an interleaved clock control mechanism according to a sixth embodiment of the present disclosure;

FIG. 7 is a circuit diagram of a single voltage regulator and a clock signal generator circuit that are included in a multiphase voltage regulation circuit having an interleaved clock control mechanism according to a seventh embodiment of the present disclosure;

FIG. 8 is a circuit diagram of a phase locking circuit inside a voltage regulator included in a multiphase voltage regulation circuit having an interleaved clock control mechanism according to an eighth embodiment of the present disclosure;

FIG. 9 is a circuit diagram of a buffer circuit inside a voltage regulator included in a multiphase voltage regulation circuit having an interleaved clock control mechanism according to a ninth embodiment of the present disclosure;

FIG. 10 is a circuit diagram of an on-time signal generator circuit inside a voltage regulator included in a multiphase voltage regulation circuit having an interleaved clock control mechanism according to a tenth embodiment of the present disclosure;

FIG. 11 is a waveform diagram of signals of a multiphase voltage regulation circuit having an interleaved clock control mechanism according to an eleventh embodiment of the present disclosure; and

FIG. 12 is a waveform diagram of signals of a multiphase voltage regulation circuit having an interleaved clock control mechanism according to a twelfth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

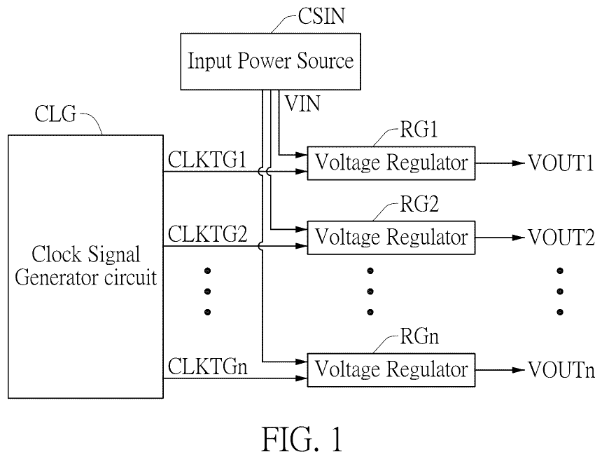

Reference is made to FIG. 1, which is a circuit diagram of a multiphase voltage regulation circuit having an interleaved clock control mechanism according to a first embodiment of the present disclosure.

As shown in FIG. 1, the multiphase voltage regulation circuit of the present disclosure includes a plurality of voltage regulators RG1 to RGn and a clock signal generator circuit CLG. The plurality of voltage regulators RG1 to RGn are connected to the clock signal generator circuit CLG.

It is worth noting that, the plurality of voltage regulators RG1 to RGn are connected to an input power source CSIN and obtain an input voltage VIN from the input power source CSIN. When a plurality of loads that are connected respectively to the plurality of voltage regulators RG1 to RGn are heavy loads requiring large power, the plurality of voltage regulators RG1 to RGn obtain the input voltage VIN having a high voltage value from the input power source CSIN at the same time. At this time, inrush waves are generated in the input voltage VIN and an input current that are supplied by the input power source CSIN. As a result, an abnormality occurs in the input power source CSIN.

In order to prevent the abnormality from occurring in the input power source CSIN, each of a plurality of voltage regulators of a conventional multiphase voltage regulation circuit includes an input capacitor that has a large capacitance and is connected to an input power source. However, the input capacitors included in the conventional multiphase voltage regulation circuit are large in size and occupy large space, resulting in an increase in an overall size of the conventional multiphase voltage regulation circuit and an increase in circuit cost.

In comparison with the conventional multiphase voltage regulation circuit including the input capacitors, no input capacitor is included in the multiphase voltage regulation circuit of the present disclosure. Therefore, a size of the multiphase voltage regulation circuit of the present disclosure is smaller than that of the conventional multiphase voltage regulation circuit. Under this condition, in order to prevent the abnormality from occurring in the input power source CSIN, the multiphase voltage regulation circuit of the present disclosure has the interleaved clock control mechanism for distributing different time intervals respectively to the plurality of voltage regulators RG1 to RGn for use of the input power CSIN, as described in detail as follows.

The clock signal generator circuit CLG generates a target clock signal having one pulse wave or plurality of pulse waves, and uses a frequency of the one pulse wave or at least one of the plurality of pulse waves as a target frequency. The clock signal generator circuit CLG multiplies the target frequency by the number of the plurality of voltage regulators RG1 to RGn to obtain a reference frequency. The signal generator circuit CLG generates a reference clock signal based on the reference frequency. A frequency of each of a plurality of pulse waves of the reference clock signal is equal to the reference frequency.

The clock signal generator circuit CLG divides the reference clock signal into a plurality of regulation clock signals CLKTG1 to CLKTGn, and outputs the plurality of regulation clock signals CLKTG1 to CLKTGn respectively to the plurality of voltage regulators RG1 to RGn.

A frequency of each of a plurality of pulse waves of the plurality of regulation clock signals CLKTG1 to CLKTGn is equal to the target frequency.

For example, the clock signal generator circuit CLG includes a frequency divider. The frequency divider is configured to divide the reference frequency into a plurality of regulation clock frequencies as a plurality of frequencies respectively of the plurality of regulation clock signals CLKTG1 to CLKTGn. Each of the plurality of regulation clock frequencies is equal to the target frequency.

It is worth noting that, the clock signal generator circuit CLG sets a plurality of phases of the plurality of pulse waves of each one of the plurality of regulation clock signals CLKTG1 to CLKTGn to be not overlapped with that of another of the plurality of regulation clock signals CLKTG1 to CLKTGn, respectively. The clock signal generator circuit CLG outputs the plurality of regulation clock signals CLKTG1 to CLKTGn respectively to the plurality of voltage regulators RG1 to RGn.

In other words, a plurality of working periods of the plurality of pulse waves of each of the plurality of regulation clock signals CLKTG1 to CLKTGn are respectively not overlapped with that of another of the plurality of regulation clock signals CLKTG1 to CLKTGn over time.

The plurality of voltage regulators RG1 to RGn obtain the input voltage VIN from the input power source CSIN, respectively based on the plurality of frequencies respectively of the plurality of regulation clock signals CLKTG1 to CLKTGn.

That is, the plurality of voltage regulators RG1 to RGn of the multiphase voltage regulation circuit of the present disclosure obtain the input voltage VIN from the input power source CSIN respectively at different time points, thereby effectively preventing the abnormality from occurring in the input power source CSIN.

After the plurality of voltage regulators RG1 to RGn obtain the input voltage VIN, the plurality of voltage regulators RG1 to RGn respectively regulate the input voltage VIN into a plurality of output voltages VOUT1 to VOUTn having different voltage values.

Output terminals of the plurality of voltage regulators RG1 to RGn may respectively output the plurality of output voltages VOUT1 to VOUTn to a plurality of loads.

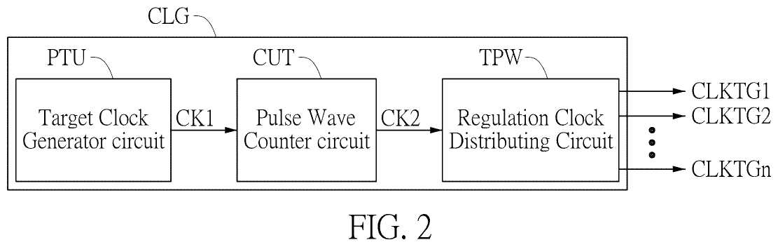

Reference is made to FIG. 2, which is a circuit diagram of a clock signal generator circuit included in a multiphase voltage regulation circuit having an interleaved clock control mechanism according to a second embodiment of the present disclosure.

The clock signal generator circuit CLG shown in FIG. 1 may be the same as the clock signal generator circuit CLG shown in FIG. 2. As shown in FIG. 2, the clock signal generator circuit CLG includes a target clock generator circuit PTU, a pulse wave counter circuit CUT and a regulation clock distributing circuit TPW.

As shown in FIG. 2, the pulse wave counter circuit CUT is connected to the target clock generator circuit PTU and the regulation clock distributing circuit TPW. The regulation clock distributing circuit TPW shown in FIG. 2 may be connected to the plurality of voltage regulators RG1 to RGn shown in FIG. 1.

The target clock generator circuit PTU generates a target clock signal CK1.

The pulse wave counter circuit CUT shown in FIG. 2 counts or stores the number of the plurality of voltage regulators RG1 to RGn shown in FIG. 1. The pulse wave counter circuit CUT uses a frequency of one pulse wave or at least one of a plurality of pulse waves of the target clock signal CK1 as the target frequency, and multiplies the target frequency by the number of the plurality of voltage regulators RG1 to RGn to obtain the reference frequency. The pulse wave counter circuit CUT outputs a reference clock signal CK2 based on the reference frequency. A frequency of each of a plurality of pulse waves of the reference clock signal CK2 is equal to the reference frequency.

The regulation clock distributing circuit TPW divides the reference clock signal CK2 into the plurality of regulation clock signals CLKTG1 to CLKTGn. The regulation clock distributing circuit TPW shown in FIG. 2 outputs the plurality of regulation clock signals CLKTG1 to CLKTGn respectively to the plurality of voltage regulators RG1 to RGn shown in FIG. 1.

The plurality of voltage regulators RG1 to RGn obtain the input voltage VIN from the input power source CSIN, respectively based on the frequencies of the plurality of regulation clock signals CLKTG1 to CLKTGn from the regulation clock distributing circuit TPW.

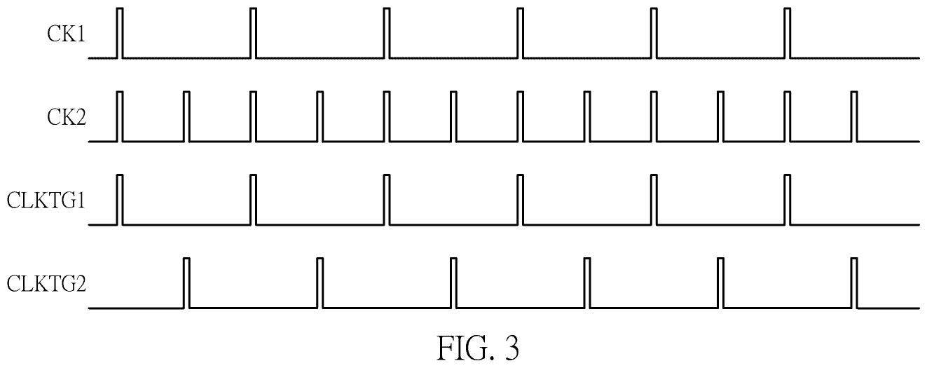

Reference is made to FIG. 3, which is a waveform diagram of signals of the multiphase voltage regulation circuit having the interleaved clock control mechanism according to a third embodiment of the present disclosure.

The clock signal generator circuit CLG shown in FIG. 1 or the target clock generator circuit PTU of the clock signal generator circuit CLG shown in FIG. 2 may generate the target clock signal CK1 shown in FIG. 3.

If the multiphase voltage regulation circuit only includes the two voltage regulators RG1 and RG2, the clock signal generator circuit CLG shown in FIG. 1 or the pulse wave counter circuit CUT of the clock signal generator circuit CLG shown in FIG. 2 multiplies the number “6” of the pulse waves of the target clock signal CK1 by the number “2” of the voltage regulators RG1 and RG2 to obtain the reference frequency “12”, and then generates the reference clock signal CK2 having 12 pulse waves shown in FIG. 3 according to the reference frequency “12”.

The clock signal generator circuit CLG shown in FIG. 1 or the regulation clock distributing circuit TPW of the clock signal generator circuit CLG shown in FIG. 2 outputs the regulation clock signal CLKTG1 to the voltage regulator RG1, according to odd ones of the plurality of pulse waves of the reference clock signal CK2 shown in FIG. 3. The working periods, non-working periods and the frequencies of the plurality of pulse waves of the regulation clock signal CLKTG1 are respectively equal to working periods, non-working periods and frequencies of the odd ones of the plurality of pulse waves of the reference clock signal CK2. That is, the working periods of the odd ones of the plurality of pulse waves of the reference clock signal CK2 shown in FIG. 3 are distributed to the voltage regulator RG1, as time intervals within which the voltage regulator RG1 obtains the input voltage VIN from the input power source CSIN shown in FIG. 1.

The clock signal generator circuit CLG shown in FIG. 1 or the regulation clock distributing circuit TPW of the clock signal generator circuit CLG shown in FIG. 2 outputs the regulation clock signal CLKTG2 to the voltage regulator RG2, according to even ones of the plurality of pulse waves of the reference clock signal CK2 shown in FIG. 3. The working periods, non-working periods and the frequencies of the plurality of pulse waves of the regulation clock signal CLKTG2 are respectively equal to working periods, non-working periods and frequencies of the even ones of the plurality of pulse waves of the reference clock signal CK2. That is, the working periods of the even ones of the plurality of pulse waves of the reference clock signal CK2 are distributed to the voltage regulator RG2, as time intervals within which the voltage regulator RG2 obtains the input voltage VIN from the input power source CSIN.

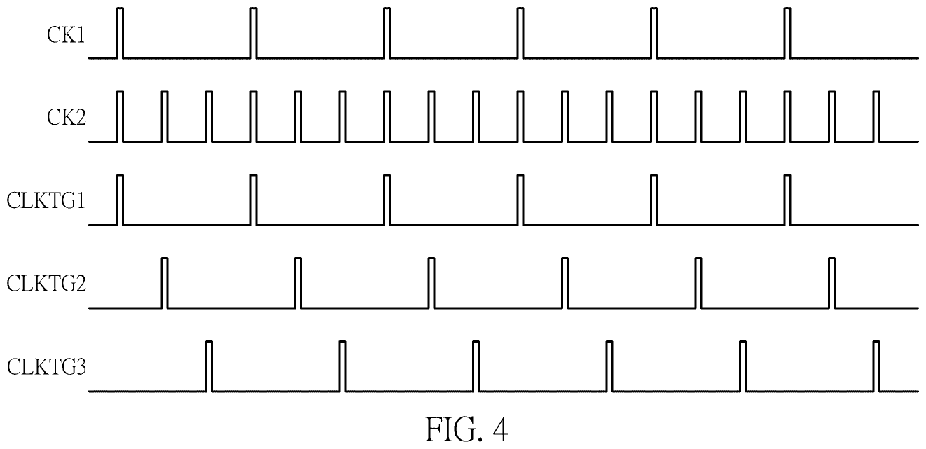

Reference is made to FIG. 4, which is a waveform diagram of signals of the multiphase voltage regulation circuit having the interleaved clock control mechanism according to a fourth embodiment of the present disclosure.

If the multiphase voltage regulation circuit includes three voltage regulators RG1 to RG3, the clock signal generator circuit CLG shown in FIG. 1 or the pulse wave counter circuit CUT of the clock signal generator circuit CLG shown in FIG. 2 multiplies the number “6” of the pulse waves of the target clock signal CK1 by the number “3” of the voltage regulators RG1 to RG3 to obtain the reference frequency “18”, and then generates the reference clock signal CK2 having 18 pulse waves shown in FIG. 4 according to the reference frequency “18”.

The clock signal generator circuit CLG shown in FIG. 1 or the regulation clock distributing circuit TPW of the clock signal generator circuit CLG shown in FIG. 2, based on the number “3” of the voltage regulators RG1 to RG3 included in the multiphase voltage regulation circuit, classifies each three adjacent ones of the plurality of pulse waves of the reference clock signal CK2 into a same one of a plurality of clock groups. The clock signal generator circuit CLG or the regulation clock distributing circuit TPW respectively distribute the three adjacent pulse waves in each of the plurality of clock groups to the three regulation clock signals CLKTG1 to CLKT3.

The three voltage regulators RG1 to RG3 respectively receive the three regulation clock signals CLKTG1 to CLKT3 each having the plurality of pulse waves from the clock signal generator circuit CLG or the regulation clock distributing circuit TPW. That is, the three working periods of the three pulse waves in each of the plurality of clock groups are respectively distributed to the three voltage regulators RG1 to RG3. The three voltage regulators RG1 to RG3 obtain the input voltage VIN from the input power source CSIN respectively within the three time intervals.

If the multiphase voltage regulation circuit includes more voltage regulators, a plurality of time intervals are respectively distributed for the more voltage regulators in the above-mentioned manner, and the more voltage regulators obtain the input voltage VIN from the input power source CSIN respectively within the plurality of time intervals.

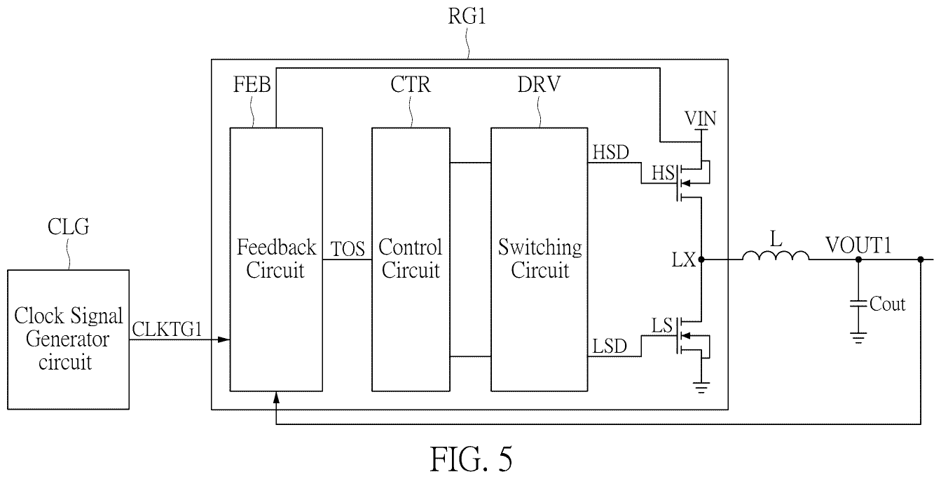

Reference is made to FIG. 5, which is a circuit diagram of a single voltage regulator and a clock signal generator circuit that are included in a multiphase voltage regulation circuit having an interleaved clock control mechanism according to a fifth embodiment of the present disclosure.

The voltage regulator RG1 included in the multiphase voltage regulation circuit of the present disclosure as shown in FIG. 1 may be the same as the voltage regulator RG1 shown in FIG. 5. In practice, internal configurations of the voltage regulators RG2 to RGn included in the multiphase voltage regulation circuit of the present disclosure may be the same as that of the voltage regulator RG1 shown in FIG. 5.

As shown in FIG. 5, the voltage regulator RG1 may include a high-side switch HS, a low-side switch LS, a feedback circuit FEB, a control circuit CTR and a switching circuit DRV.

A first terminal of the high-side switch HS is coupled to the input voltage VIN shown in FIG. 5, or in practice, is connected to the input power source CSIN shown in FIG. 1. A first terminal of the high-side switch HS is connected to a second terminal of the high-side switch HS. A second terminal of the low-side switch LS is grounded. An output node LX between the first terminal of the high-side switch HS and the second terminal of the high-side switch HS is connected to a first terminal of an inductor L. A second terminal of the inductor L may be connected to a first terminal of an output capacitor Cout. A second terminal of the output capacitor Cout is grounded. The second terminal of the inductor L or the output capacitor Cout is used as an output terminal of the voltage regulator RG1, and may be connected to a load.

It is worth noting that, the clock signal generator circuit CLG is connected to the feedback circuit FEB of the voltage regulator RG1. The feedback circuit FEB, based on the frequency of the regulation clock signal CLKTG1 from the clock signal generating circuit CLG, sets a working period of each of a plurality of waveforms (such as pulse waves) of an on-time signal TOS according to the input voltage VIN received by the first terminal of the high-side switch HS and the output voltage VOUT1 of the second terminal of the inductor L.

The control circuit CTR is connected to the feedback circuit FEB. The control circuit CTR outputs a high-side control signal and a low-side control signal according to the on-time signal TOS from the feedback circuit FEB.

The switching circuit DRV is connected to the control circuit CTR, a control terminal of the high-side switch HS and a control terminal of the low-side switch LS. The switching circuit DRV outputs a high-side driving signal HSD to the control terminal of the high-side switch HS according to the high-side control signal from the control circuit CTR. The switching circuit DRV outputs a low-side driving signal LSD to the control terminal of the low-side switch LS according to the low-side control signal from the control circuit CTR.

In brief, in the multiphase voltage regulation circuit of the present disclosure, the high-side switch HS and the low-side switch LS of the voltage regulator RG1 are controlled based on the frequencies of the regulation clock signal CLKTG1 from the clock signal generator circuit CLG.

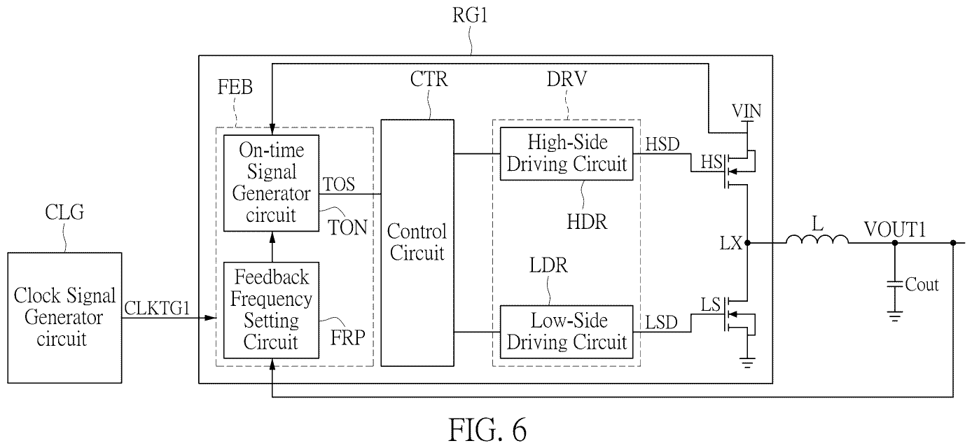

Reference is made to FIG. 6, which is a circuit diagram of a single voltage regulator and a clock signal generator circuit that are included in a multiphase voltage regulation circuit having an interleaved clock control mechanism according to a sixth embodiment of the present disclosure.

The descriptions of the sixth embodiment of the present disclosure that are the same as the descriptions of the fifth embodiment of the present disclosure are not repeated herein.

As shown in FIG. 6, the feedback circuit FEB may include an on-time signal generator circuit TON and a feedback frequency setting circuit FRP. The switching circuit DRV may include a high-side driving circuit HDR and a low-side driving circuit LDR.

The feedback frequency setting circuit FRP is connected to the clock signal generator circuit CLG and the second terminal of the inductor L. The feedback frequency setting circuit FRP, based on the regulation clock signal CLKTG1 from the clock signal generator circuit CLG, sets a frequency of outputting the output voltage VOUT1 of the second terminal of the inductor L to the on-time signal generator circuit TON. In other words, the feedback frequency setting circuit FRP outputs the output voltage VOUT1 of the second terminal of the inductor L to the on-time signal generator circuit TON, within the working period of each of the plurality of pulse waves of the regulation clock signal CLKTG1.

The on-time signal generator circuit TON is connected to the first terminal of the high-side switch HS, the feedback frequency setting circuit FRP and the control circuit CTR. The on-time signal generator circuit TON sets duty cycles of the plurality of waveforms of the on-time signal TOS, according to the output voltage VOUT1 of the second terminal of the inductor L from the feedback frequency setting circuit FRP and the input voltage VIN received by the first terminal of the high-side switch HS. The on-time signal generator circuit TON outputs the on-time signal TOS.

The control circuit CTR outputs the high-side control signal and the low-side control signal according to the on-time signal TOS from the on-time signal generator circuit TON.

The high-side driving circuit HDR is connected to the control circuit CTR and the control terminal of the high-side switch HS. The high-side driving circuit HDR outputs the high-side driving signal HSD to the control terminal of the high-side switch HS according to the high-side control signal from the control circuit CTR.

The low-side driving circuit LDR is connected to the control circuit CTR and the control terminal of the low-side switch HS. The low-side driving circuit LDR outputs the low-side driving signal LSD to the control terminal of the low-side switch LS according to the low-side control signal from the control circuit CTR.

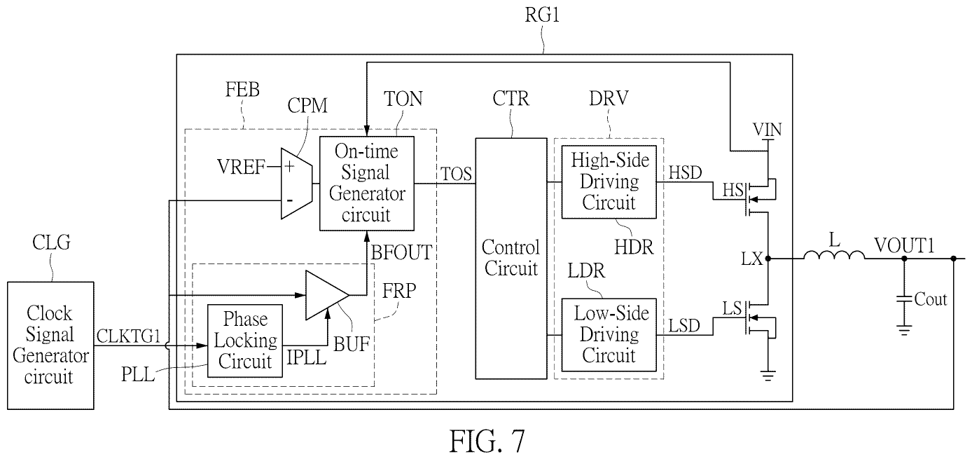

Reference is made to FIG. 7, which is a circuit diagram of a single voltage regulator and a clock signal generator circuit that are included in a multiphase voltage regulation circuit having an interleaved clock control mechanism according to a seventh embodiment of the present disclosure.

The descriptions of the seventh embodiment of the present disclosure that are the same as the descriptions of the sixth embodiment of the present disclosure are not repeated herein.

As shown in FIG. 7, the feedback circuit FEB not only includes the on-time signal generator circuit TON and the feedback frequency setting circuit FRP, but also includes a compensation circuit CPM.

The feedback frequency setting circuit FRP shown in FIG. 5 may be the same as the feedback frequency setting circuit FRP shown in FIG. 7.

As shown in FIG. 7, the feedback frequency setting circuit FRP may include a buffer circuit BUF and a phase locking circuit PLL. The buffer circuit BUF may include a buffer. An input terminal of the phase locking circuit PLL is connected to an output terminal of the clock signal generator circuit CLG. An input terminal of the buffer circuit BUF is connected to the second terminal of the inductor L. A control terminal of the buffer circuit BUF is connected to an output terminal of the phase locking circuit PLL, and an output terminal of the buffer circuit BUF is connected to the on-time signal generator circuit TON.

The phase locking circuit PLL outputs a phase locking current IPLL to the control terminal of the buffer circuit BUF, based on the frequencies of the regulation clock signal CLKTG1 from the clock signal generator circuit CLG. In other words, the buffer circuit BUF outputs a buffered voltage signal BFOUT corresponding to the phase locking current IPLL to the on-time signal generator circuit TON, within the working period of each of the plurality of pulse waves of the regulation clock signal CLKTG1. As a result, a frequency and a time point at which the buffer circuit BUF outputs the buffered voltage signal BFOUT to the on-time signal generator circuit TON according to the output voltage VOUT1 from the second terminal of the inductor L are controlled.

The on-time signal generator circuit TON sets the duty cycles of the plurality of waveforms of the on-time signal TOS, according to the buffered voltage signal BFOUT from the buffer circuit BUF and the input voltage VIN received by the first terminal of the high-side switch HS. The on-time signal generator circuit TON outputs the on-time signal TOS to the control circuit CTR.

If necessary, a first input terminal of the compensation circuit CPM may be coupled to a reference voltage VREF, a second input terminal of the compensation circuit CPM may be connected to the second terminal of the inductor L (through a voltage dividing circuit). An output terminal of the compensation circuit CPM may be connected to the on-time signal generator circuit TON. The compensation circuit CPM may compare the output voltage VOUT1 of the second terminal of the inductor L or a divided voltage of the output voltage VOUT1 with the reference voltage VREF to output a compensation signal. The on-time signal generator circuit TON may set or modulate the on-time signal TOS according to the compensation signal from the compensation circuit CPM.

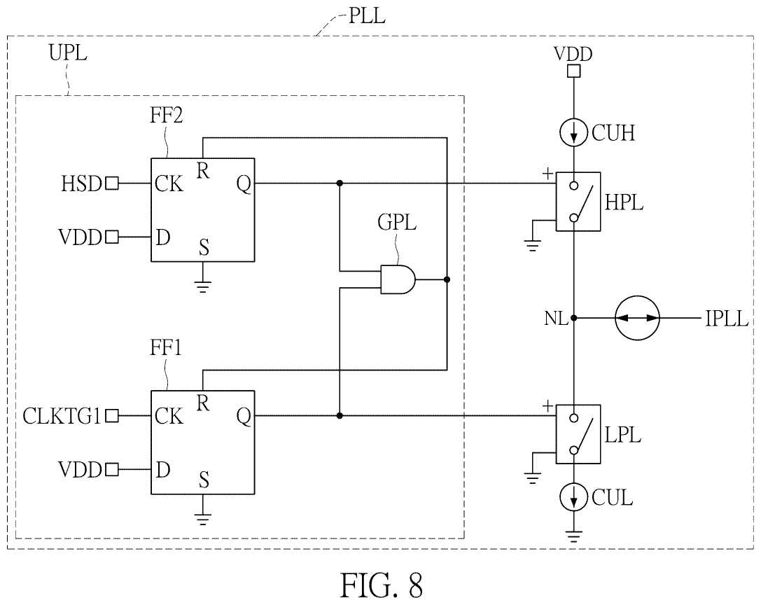

Reference is made to FIG. 8, which is a circuit diagram of a phase locking circuit inside a voltage regulator included in a multiphase voltage regulation circuit having an interleaved clock control mechanism according to an eighth embodiment of the present disclosure.

The phase locking circuit PLL shown in FIG. 7 may be the same as the phase locking circuit PLL shown in FIG. 8.

As shown in FIG. 8, the phase locking circuit PLL includes a regulation clock locking circuit UPL, a high-side phase locking switch HPL and a low-side phase locking switch LPL. If necessary, the phase locking circuit PLL may further include a high-side current source CUH, a low-side current source CUL or a combination thereof.

For example, the regulation clock locking circuit UPL may include a first flip-flop FF1, a second flip-flop FF2 and a phase locking logic gate GPL. The first flip-flop FF1 and the second flip-flop FF2 may be SR flip-flops, and the phase locking logic gate GPL may be a AND gate.

A clock receiving terminal CK of the first flip-flop FF1 is connected to the clock signal generator circuit CLG, and receive the regulation clock signal CLKTG1 from the clock signal generator circuit CLG. A first input terminal R of the first flip-flop FF1 is connected to an output terminal of the phase locking logic gate GPL. A second input terminal S of the first flip-flop FF1 is grounded. A power input terminal D of the first flip-flop FF1 is coupled to a common voltage VDD. An output terminal Q of the first flip-flop FF1 is connected to a first input terminal of the phase locking logic gate GPL and a control terminal of the low-side phase locking switch LPL.

The clock receiving terminal CK of the second flip-flop FF2 is connected to the control terminal of the high-side switch HS and an output terminal of the high-side driving circuit HDR, and obtains the high-side driving signal HSD that is outputted from the output terminal of the high-side driving circuit HDR to the control terminal of the high-side switch HS. The first input terminal R of the second flip-flop FF2 is connected to the output terminal of the phase locking logic gate GPL. The second input terminal S of the second flip-flop FF2 is grounded. The power input terminal D of the second flip-flop FF2 is coupled to the common voltage VDD. The output terminal Q of the second flip-flop FF2 is connected to a second input terminal of the phase locking logic gate GPL and a control terminal of the high-side phase locking switch HPL.

A first terminal of the high-side current source CUH is coupled to the common voltage VDD. A second terminal of the high-side current source CUH is connected to a first terminal of the high-side phase locking switch HPL. A second terminal of the high-side phase locking switch HPL is connected to a first terminal of the low-side phase locking switch LPL. A second terminal of the low-side phase locking switch LPL is connected to a first terminal of the low-side current source CUL. A second terminal of the low-side current source CUL is grounded.

The high-side current source CUH is configured to supply a high-side current to the high-side phase locking switch HPL. The high-side current source CUH is configured to pull down the phase locking current IPLL of a phase locking node NL between the second terminal of the high-side phase locking switch HPL and the first terminal of the low-side phase locking switch LPL.

The regulation clock locking circuit UPL, based on the regulation clock signal CLKTG1 (and the high-side driving signal HSD), outputs the high-side phase locking signal to the control terminal of the high-side phase locking switch HPL and outputs the low-side phase locking signal to the control terminal of the low-side phase locking switch LPL. As a result, the high-side phase locking switch HPL and the low-side phase locking switch LPL are controlled so as to control the phase locking current IPLL of the phase locking node NL between the second terminal of the high-side phase locking switch HPL and the first terminal of the low-side phase locking switch LPL.

The phase locking node NL between the second terminal of the high-side phase locking switch HPL and the first terminal of the low-side phase locking switch LPL as shown in FIG. 8 may be used as the output terminal of the phase locking circuit PLL shown in FIG. 7, and outputs the phase locking current IPLL to the control terminal of the buffer circuit BUF shown in FIG. 7.

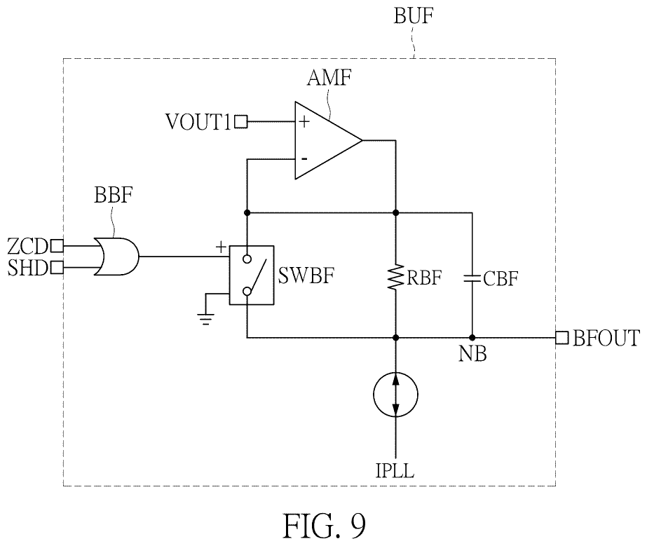

Reference is made to FIG. 9, which is a circuit diagram of a buffer circuit inside a voltage regulator included in a multiphase voltage regulation circuit having an interleaved clock control mechanism according to a ninth embodiment of the present disclosure.

The buffer circuit BUF shown in FIG. 7 may be the same as the buffer circuit BUF shown in FIG. 9. As shown in FIG. 9, the buffer circuit BUF includes an operational amplifier as a buffer operational amplifier AMF. If necessary, the buffer circuit BUF may further include a buffer resistor RBF, a buffer capacitor CBF, a buffer switch SWBF, a buffer logic gate BBF (such as, but not limited to, an OR gate), or any combination thereof.

A first input terminal such as a non-inverting input terminal of the buffer operational amplifier AMF is connected to the second terminal of the inductor L, and receives the output voltage VOUT1 from the second terminal of the inductor L. A second input terminal such as an inverting input terminal of the buffer operational amplifier AMF is connected to an output terminal of the buffer operational amplifier AMF, a first terminal of the buffer resistor RBF, a first terminal of the buffer capacitor CBF and a first terminal of the buffer switch SWBF.

It is worth noting that, the buffering node NB to which a second terminal of the buffer resistor RBF, a second terminal of the buffer capacitor CBF and a second terminal of the buffer switch SWB are connected and used as the control terminal of the buffer circuit BUF. The buffering node NB shown in FIG. 9 may be connected to the phase locking node NL between the second terminal of the high-side phase locking switch HPL and the first terminal of the low-side phase locking switch LPL as shown in FIG. 8, and receives the phase locking circuit PLL from the phase locking node NL.

A control terminal of the buffer switch SWBF may be connected to an output terminal of the buffer logic gate BBF (such as, but not limited to, the OR gate) as shown in FIG. 9, or in practice, may be coupled to a variable control voltage. An external zero current detector circuit detects a current flowing through the inductor L. When the external zero current detector circuit determines that the current flowing through the inductor L reaches a zero current value, the external zero current detector circuit outputs a zero current detected logic signal ZCD at a high level to a first input terminal of the buffer logic gate BBF. Conversely, when the external zero current detector circuit determines that the current flowing through the inductor L does not reach the zero current value, the external zero current detector circuit outputs the zero current detected logic signal ZCD at a low level to the first input terminal of the buffer logic gate BBF. An external shielding signal generator circuit may output a shielding signal SHD to a second input terminal of the buffer logic gate BBF. Time during which the shielding signal SHD is at a low level is a non-working period of a waveform of the shielding signal SHD and is used as a shielding time. The buffer logic gate BBF stops switching the buffer switch SWBF according to the zero current detected logic signal ZCD during the shielding time.

The buffering node NB of the buffer circuit BUF shown in FIG. 9 may be connected to the on-time signal generator circuit TON shown in FIG. 7. The on-time signal generator circuit TON may set the working periods and the duty cycles of the plurality of waveforms of the on-time signal TOS, according to the buffered voltage signal BFOUT from the buffering node NB of the buffer circuit BUF and the input voltage VIN received by the first terminal of the high-side switch HS. The on-time signal generator circuit TON outputs the on-time signal TOS to the control circuit CTR.

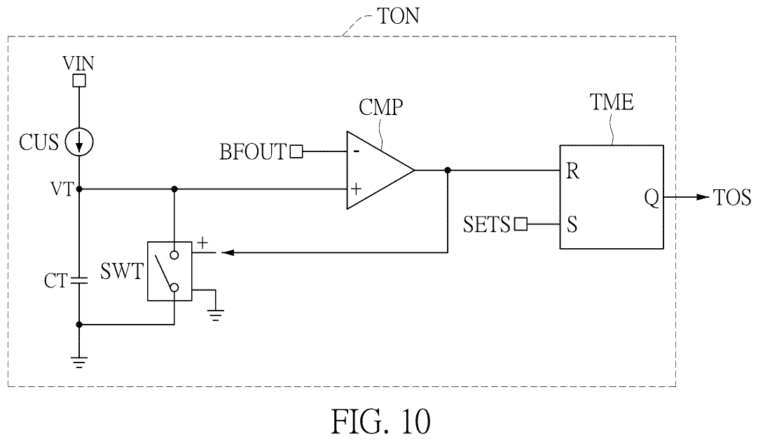

Reference is made to FIG. 10, which is a circuit diagram of an on-time signal generator circuit inside a voltage regulator included in a multiphase voltage regulation circuit having an interleaved clock control mechanism according to a tenth embodiment of the present disclosure.

The on-time signal generator circuit TON shown in FIG. 7 may be the same as the on-time signal generator circuit TON shown in FIG. 10. As shown in FIG. 10, the on-time signal generator circuit TON may include a comparator CMP and an on-time setting circuit TME. If necessary, the on-time signal generator circuit TON may further include a setting current source CUS, a setting capacitor CT, a reset switch SWT, or a combination thereof.

A first terminal of the setting current source CUS is coupled to the input voltage VIN. A second terminal of the setting current source CUS is connected to a first terminal of the setting capacitor CT. A second terminal of the setting capacitor CT is grounded. The setting capacitor CT supplies a charging current to the setting capacitor CT by using the input voltage VIN for charging the setting capacitor CT such that a set voltage VT of the setting capacitor CT is gradually increased.

A first input terminal such as an inverting input terminal of the comparator CMP shown in FIG. 10 is connected to the buffering node NB of the buffer circuit BUF shown in FIG. 9, and receives the buffered voltage signal BFOUT from the buffering node NB of the buffer circuit BUF. A second input terminal such as a non-inverting input terminal of the comparator CMP is connected to the first terminal of the setting capacitor CT, and receives the set voltage VT from the first terminal of the setting capacitor CT.

The comparator CMP compares a voltage of the buffered voltage signal BFOUT from the buffering node NB of the buffer circuit BUF with the set voltage VT to output a comparing signal.

The reset switch SWT operates according to the comparing signal from the comparator CMP. When the control terminal of the reset switch SWT receives the comparing signal at a high level, the reset switch SWT is turned on. As a result, the set voltage VT of the second input terminal such as the non-inverting input terminal of the comparator CMP is reset to a zero voltage value.

For example, the on-time setting circuit TME may be a SR flip-flop. The first input terminal R of the on-time setting circuit TME is connected to an output terminal of the comparator CMP. The second input terminal of the on-time setting circuit TME may be coupled to a set logic level SETS. The output terminal Q of the on-time setting circuit TME shown in FIG. 10 is connected to the control circuit CTR shown in FIG. 7, and outputs the on-time signal TOS to the control circuit CTR.

The on-time setting circuit TME shown in FIG. 10, according to the comparing signal from the output terminal of the comparator CMP (and the set logic level SETS), outputs the on-time signal TOS to the control circuit CTR shown in FIG. 7.

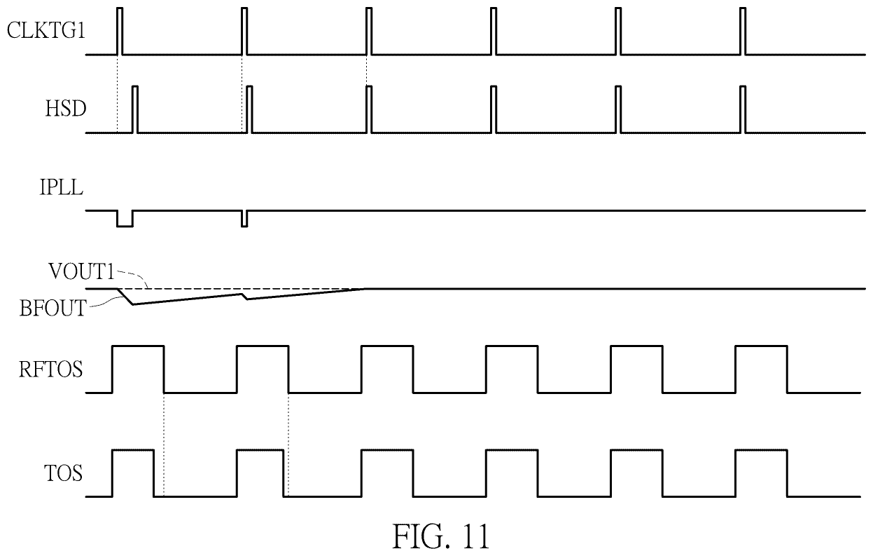

Reference is made to FIG. 11, which is a waveform diagram of signals of a multiphase voltage regulation circuit having an interleaved clock control mechanism according to an eleventh embodiment of the present disclosure.

The regulation clock signal CLKTG1 among the plurality of regulation clock signals CLKTG1 to CLKTGn that are respectively outputted to the plurality of voltage regulators RG1 to RGn by the clock signal generator circuit CLG shown in FIG. 7 may be the same as the regulation clock signal CLKTG1 shown in FIG. 11.

The high-side driving signal HSD that is outputted to the control terminal of the high-side switch HS by the high-side driving circuit HDR shown in FIG. 7 may be the same as the high-side driving signal HSD shown in FIG. 11.

The phase locking current IPLL outputted by the phase locking circuit PLL shown in FIG. 7 may be the same as the phase locking current IPLL shown in FIG. 11.

The buffered voltage signal BFOUT outputted by the buffer circuit BUF shown in FIG. 7 may be the same as the buffered voltage signal BFOUT shown in FIG. 11.

The on-time signal TOS outputted by the on-time signal generator circuit TON shown in FIG. 7 may be the same as the on-time signal TOS shown in FIG. 11.

As shown in FIG. 11, the working periods of earlier ones of the plurality of pulse waves of the on-time signal TOS (as on-times of the high-side switch HS) are respectively smaller than working periods of earlier ones of a plurality of pulse waves of a reference on-time signal RFTOS. At this time, phases of earlier ones of a plurality of pulse waves of the high-side driving signal HSD respectively delay with respect to the phases of earlier ones of the plurality of pulse waves of the regulation clock signal CLKTG1. At this time, the phase locking current IPLL that is outputted to the control terminal of the buffer circuit BUF by the phase locking circuit PLL has negative current values or a half waveform having the negative current values. As a result, a voltage of the buffered voltage signal BFOUT that is outputted by the buffer circuit BUF is lower than the output voltage VOUT1 of the second terminal of the inductor L.

The later ones of the plurality of pulse waves of the high-side driving signal HSD are respectively aligned with the plurality of pulse waves of the regulation clock signal CLKTG1. At this time, the working periods of later ones of the plurality of pulse waves of the high-side driving signal HSD are respectively increased to be equal to working periods of later ones of the plurality of pulse waves of the reference on-time signal RFTOS. The phase locking circuit PLL outputs the phase locking current IPLL having a zero current value to the control terminal of the buffer circuit BUF. As a result, the voltage of the buffered voltage signal BFOUT that is outputted according to the phase locking current IPLL having the zero current value by the buffer circuit BUF is equal to the output voltage VOUT1 of the second terminal of the inductor L. At this time, the plurality of pulse waves of the high-side driving signal HSD are respectively aligned with the plurality of pulse waves of the regulation clock signal CLKTG1.

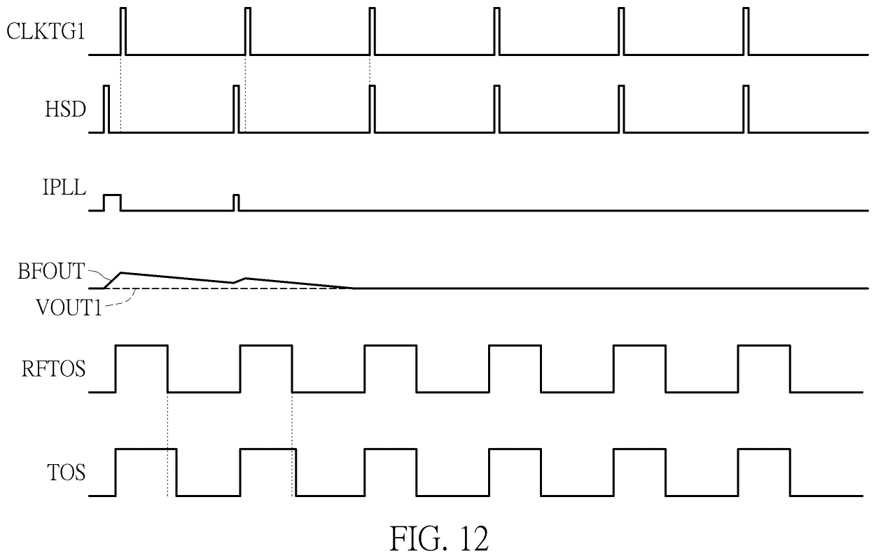

Reference is made to FIG. 12, which is a waveform diagram of signals of a multiphase voltage regulation circuit having an interleaved clock control mechanism according to a twelfth embodiment of the present disclosure.

The regulation clock signal CLKTG1 among the plurality of regulation clock signals CLKTG1 to CLKTGn that are respectively outputted to the plurality of voltage regulators RG1 to RGn by the clock signal generator circuit CLG shown in FIG. 7 may be the same as the regulation clock signal CLKTG1 shown in FIG. 12.

The high-side driving signal HSD that is outputted by the high-side driving circuit HDR shown in FIG. 7 may be the same as the high-side driving signal HSD shown in FIG. 12.

The phase locking current IPLL outputted by the phase locking circuit PLL shown in FIG. 7 may be the same as the phase locking current IPLL shown in FIG. 12.

The buffered voltage signal BFOUT outputted by the buffer circuit BUF shown in FIG. 7 may be the same as the buffered voltage signal BFOUT shown in FIG. 12.

The on-time signal TOS outputted by the on-time signal generator circuit TON shown in FIG. 7 may be the same as the on-time signal TOS shown in FIG. 12.

As shown in FIG. 12, the working periods of earlier ones of the plurality of pulse waves of the on-time signal TOS (as the on-times of the high-side switch HS) are respectively larger than the working periods of earlier ones of the plurality of pulse waves of the reference on-time signal RFTOS. At this time, the phases of earlier ones of the plurality of pulse waves of the high-side driving signal HSD respectively lead with respect to the phases of earlier ones of the plurality of pulse waves of the regulation clock signal CLKTG1. At this time, the phase locking current IPLL that is outputted to the control terminal of the buffer circuit BUF by the phase locking circuit PLL has positive current values or a half waveform having the positive current values. As a result, the voltage of the buffered voltage signal BFOUT that is outputted by the buffer circuit BUF is higher than the output voltage VOUT1 of the second terminal of the inductor L.

The later ones of the plurality of pulse waves of the high-side driving signal HSD are respectively aligned with the plurality of pulse waves of the regulation clock signal CLKTG1. At this time, the working periods of later ones of the plurality of pulse waves of the high-side driving signal HSD are increased respectively to be equal to the working periods of later ones of the plurality of pulse waves of the reference on-time signal RFTOS. The phase locking circuit PLL outputs the phase locking current IPLL having the zero current value to the control terminal of the buffer circuit BUF. As a result, the voltage of the buffered voltage signal BFOUT that is outputted according to the phase locking current IPLL having the zero current value by the buffer circuit BUF is equal to the output voltage VOUT1 of the second terminal of the inductor L. At this time, the plurality of pulse waves of the high-side driving signal HSD are respectively aligned with the plurality of pulse waves of the regulation clock signal CLKTG1.

In conclusion, the present disclosure provides the multiphase voltage regulation circuit having the interleaved clock control mechanism. The plurality of voltage regulators included in the multiphase voltage regulation circuit of the present disclosure obtain the input voltage from the input power source respectively at different time points, thereby effectively preventing large ripple waves from generating in the input voltage and the input current of the input power source. Therefore, the multiphase voltage regulation circuit of the present disclosure is capable of preventing the abnormality from occurring in the input power source under the condition that size of the multiphase voltage regulation circuit of the present disclosure is not increased.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A multiphase voltage regulation circuit having an interleaved clock control
mechanism, comprising:
a plurality of voltage regulators; and
a clock signal generator circuit connected to the plurality of voltage regulators;
wherein the clock signal generator circuit is configured to:
use a frequency of a pulse wave of a target clock signal as a target frequency;
multiply the target frequency by a number of the plurality of voltage regulators to obtain a reference frequency;
generate a reference clock signal based on the reference frequency, wherein a frequency of each of a plurality of pulse waves of the reference clock signal is equal to the reference frequency; and
divide the reference clock signal into a plurality of regulation clock signals and output the plurality of regulation clock signals respectively to the plurality of voltage regulators, wherein a frequency of each of a plurality of pulse waves of the plurality of regulation clock signals is equal to the target frequency, and a plurality of phases of the plurality of pulse waves of each one of the plurality of regulation clock signals are respectively not overlapped with that of another of the plurality of regulation clock signals;
wherein each of the plurality of voltage regulators is configured to obtain an input voltage from an input power source based on the regulation clock signal, and configured to modulate the input voltage into an output voltage.

2. The multiphase voltage regulation circuit according to claim 1, wherein the clock signal generator circuit includes:
a target clock generator circuit configured to generate the target clock signal;
a pulse wave counter circuit connected to the target clock generating circuit, and configured to multiply the target frequency of the target clock signal by the number of the plurality of voltage regulators to obtain the reference frequency; and
a regulation clock distributing circuit connected to the pulse wave counter circuit, wherein the regulation clock distributing circuit is configured to generate the reference clock signal based on the reference frequency, divide the reference clock signal into a plurality of regulation clock signals, and output the plurality of regulation clock signals respectively to the plurality of voltage regulators.

3. The multiphase voltage regulation circuit according to claim 1, wherein each of the plurality of voltage regulators includes:
a high-side switch, wherein a first terminal of the high-side switch is connected to the input power source and receives the input voltage from the input power source;
a low-side switch, wherein a first terminal of the low-side switch is connected to a second terminal of the high-side switch, a second terminal of the high-side switch is grounded, and a second terminal of the high-side switch is connected to a first terminal of an inductor; and
a feedback circuit connected to the clock signal generator circuit, the first terminal of the high-side switch and a second terminal of the inductor, and configured to output an on-time signal according to the input voltage and the output voltage of the second terminal of the inductor based on the regulation clock signal.

4. The multiphase voltage regulation circuit according to claim 3, wherein each of the plurality of voltage regulators further includes:
a control circuit connected to the feedback circuit, and configured to output a high-side control signal and a low-side control signal according to the on-time signal; and
a switching circuit connected to the control circuit, a control terminal of the high-side switch and a control terminal of the high-side switch, wherein the switching circuit is configured to output a high-side driving signal to the control terminal of the high-side switch according to the high-side control signal, and configured to output a low-side driving signal to the control terminal of the low-side switch according to the low-side control signal.

5. The multiphase voltage regulation circuit according to claim 4, wherein the feedback circuit includes:
a feedback frequency setting circuit connected to the clock signal generator circuit and the second terminal of the inductor, and configured to output the output voltage of the second terminal of the inductor based on the regulation clock signal; and
an on-time signal generator circuit connected to the first terminal of the high-side switch, the feedback frequency setting circuit and the control circuit, and configured to output the on-time signal according to the input voltage and the output voltage.

6. The multiphase voltage regulation circuit according to claim 5, further comprising:
a compensation circuit connected to the second terminal of the inductor and the on-time signal generating circuit, and configured to compare the output voltage or a divided voltage of the output voltage with a reference voltage to output a compensation signal;
wherein the on-time signal generator circuit is configured to set or modulate the on-time signal according to the compensation signal.

7. The multiphase voltage regulation circuit according to claim 5, wherein the feedback frequency setting circuit includes:
a buffer circuit connected to the second terminal of the inductor and the on-time signal generator circuit; and
a phase locking circuit connected to the clock signal generator circuit and the buffer circuit, and configured to control the buffer circuit to output the output voltage of the second terminal of the inductor to the on-time signal generating circuit based on the regulation clock signal.

8. The multiphase voltage regulation circuit according to claim 7, wherein the phase locking circuit includes:
a regulation clock locking circuit connected to the clock signal generator circuit, and configured to output a high-side phase locking signal and a low-side phase locking signal based on the regulation clock signal;
a high-side phase locking switch, wherein a first terminal of the high-side phase locking switch is coupled to a common voltage, and a control terminal of the high-side phase locking switch is configured to receive the high-side phase locking signal from the regulation clock locking circuit connected thereto; and
a low-side phase locking switch, wherein a first terminal of the low-side phase locking switch is connected to a second terminal of the high-side phase locking switch, a second terminal of the low-side phase locking switch is coupled to a reference voltage level, and a control terminal of the low-side phase locking switch is configured to receive the low-side phase locking signal from the regulation clock locking circuit connected thereto;
wherein a phase locking node between the first terminal of the low-side phase locking switch and the second terminal of the high-side phase locking switch is connected to the buffer circuit.

9. The multiphase voltage regulation circuit according to claim 8, wherein the regulation clock locking circuit includes:
a first flip-flop, wherein a clock receiving terminal of the first flip-flop is configured to receive the clock signal generator circuit from the clock signal generator circuit connected thereto, and an output terminal of the first flip-flop is connected to the control terminal of the low-side phase locking switch;
a second flip-flop, wherein a clock receiving terminal of the second flip-flop is configured to receive the high-side driving signal from the control terminal of the high-side switch that is connected thereto, and an output terminal of the second flip-flop is connected to the control terminal of the high-side phase locking switch; and
a phase locking logic gate, wherein a first input terminal of the phase locking logic gate is connected to the output terminal of the first flip-flop, a second input terminal of the phase locking logic gate is connected to the output terminal of the second flip-flop, and an output terminal of the phase locking logic gate is connected to a first input terminal of the first flip-flop and a first input terminal of the second flip-flop.

10. The multiphase voltage regulation circuit according to claim 9, wherein a second input terminal of the first flip-flop and a second input terminal of the second flip-flop are grounded.

11. The multiphase voltage regulation circuit according to claim 9, wherein a power input terminal of the first flip-flop and a power input terminal of the second flip-flop are coupled to a common voltage.

12. The multiphase voltage regulation circuit according to claim 8, wherein the phase locking circuit further includes:
a high-side current source connected to the first terminal of the high-side phase locking switch.

13. The multiphase voltage regulation circuit according to claim 8, wherein the phase locking circuit further includes:
a low-side current source connected to the second terminal of the low-side phase locking switch.

14. The multiphase voltage regulation circuit according to claim 8, wherein the buffer circuit includes:
a buffer operational amplifier, wherein a first input terminal of the buffer operational amplifier is connected to the second terminal of the inductor, and a second input terminal and an output terminal of the buffer operational amplifier are connected to the phase locking node.

15. The multiphase voltage regulation circuit according to claim 14, wherein the buffer circuit further includes:
a buffer resistor, wherein a first terminal of the buffer resistor is connected to the second input terminal of the buffer operational amplifier, and a second terminal of the buffer resistor is connected to the phase locking node.

16. The multiphase voltage regulation circuit according to claim 14, wherein the buffer circuit further includes:
a buffer capacitor, wherein a first terminal of the buffer capacitor is connected to the second input terminal of the buffer operational amplifier, and a second terminal of the buffer capacitor is connected to the phase locking node.

17. The multiphase voltage regulation circuit according to claim 14, wherein the buffer circuit further includes:
a buffer switch, wherein a first terminal of the buffer switch is connected to the second input terminal of the buffer operational amplifier, a second terminal of the buffer switch is connected to the phase locking node, and a control terminal of the buffer switch is coupled to a variable control voltage.

18. The multiphase voltage regulation circuit according to claim 14, wherein the on-time signal generator circuit includes:
a comparator, wherein a first input terminal of the comparator is connected to the output terminal of the buffer operational amplifier, and a second input terminal of the comparator is coupled to a set voltage; and
an on-time setting circuit connected to an output terminal of the comparator, and configured to output the on-time signal according to a comparing signal from the output terminal of the comparator.

19. The multiphase voltage regulation circuit according to claim 18, wherein the on-time signal generator circuit further includes:
a setting current source; and
a setting capacitor, wherein a first terminal of the setting capacitor is connected to the setting current source and the second input terminal of the comparator, and a second terminal of the setting capacitor is grounded.

20. The multiphase voltage regulation circuit according to claim 18, wherein the on-time signal generator circuit further includes:
a reset switch, wherein a first terminal of the reset switch is connected to the second input terminal of the comparator, a second terminal of the reset switch is grounded, and a control terminal of the reset switch is connected to the output terminal of the comparator.
